(19) United States
(12) Patent Application Publication
(10) Pub. No.: US 2025/0389597 A1
(43) Pub. Date: Dec. 25, 2025

(54) Directing Magnetic Fields to Amplify the Measurement Signal of Magnetostrictive Torque Sensors

(71) Applicant: NCTE AG, Oberhaching (DE)

(72) Inventor: Florian Eckschlager, Riemerling (DE)

(21) Appl. No.: 19/240,686

(22) Filed: Jun. 17, 2025

(30) Foreign Application Priority Data
Jun. 24, 2024 (EP) 24183933.1

(51) Int. Cl. G01L 3/10; G01R 33/07; G01R 33/09

(52) U.S. Cl. CPC G01L 3/103; G01R 33/072; G01R 33/091

(57) ABSTRACT

A torque sensor comprises: a shaft having a first magnetized region which generates a first magnetic field in response to a torque applied to the shaft; a first magnetic field sensor for detecting the first magnetic field, the magnetic field sensor being adapted to output a signal in response to a strength of the first magnetic field at the location of the first magnetic field sensor; and a first magnetic field guiding arrangement for guiding the first magnetic field to the location of the first magnetic field sensor.

### CROSS-REFERENCE TO RELATED APPLICATION(S)

This application claims priority to European Patent Application Serial No. EP 24183933.1, filed Jun. 24, 2024, the entire disclosure of which is hereby incorporated by reference.

### TECHNICAL FIELD

The invention relates to a torque sensor based on the effect of magnetostriction. In particular, the invention relates to the directing of magnetic fields to amplify the measurement signal of magnetostrictive torque sensors

### BACKGROUND

Torque sensors are known in the prior art. An example of such a torque sensor, which is based on the principle of the inverse magnetostrictive effect, is disclosed in EP 3 050 790 B1. Here, a magnetized shaft generates a corresponding magnetic field outside the shaft as a function of an applied torque, which can be detected without contact using a magnetic field sensor. Such a magnetostrictive torque sensor therefore essentially consists of two components, on the one hand a magnetized area of the shaft and on the other hand the magnetic field sensor for detecting the magnetic field from the magnetized area under load.

The measurement of magnetic field changes caused by a torque can be carried out by measuring coils in a measuring circuit, which are influenced by the changing magnetic field. In another variant, magnetic field sensors based on a magnetoresistive effect are used, which can detect not only the strength of the magnetic field, but also the direction of the magnetic field.

These measuring coils or magnetic field sensors are mounted without contact in relation to the magnetized shaft (e.g. parallel to the axis of rotation) and detect magnetic field changes that occur under load due to inverse magnetostriction. The magnetic field change is usually directly proportional to the external force and establishes the relationship with the torque. For this purpose, a calibration is carried out during the manufacturing phase of the torque sensor.

Because the strengths of the magnetic fields generated, particularly at low torques, are only low at the point of measurement, this can result in a low signal-to-noise ratio, combined with a corresponding uncertainty in the torque measurement values of the torque sensor.

### SUMMARY

The invention is based on the problem of at least partially eliminating the aforementioned disadvantages.

This problem is solved by a torque sensor according to patent claim 1.

According to patent claim 1, the torque sensor according to the invention comprises the following features: a shaft having a first magnetized region which generates a first magnetic field as a function of a torque applied to the shaft; a first magnetic field sensor for detecting the first magnetic field, the magnetic field sensor being adapted to output a signal as a function of a strength of the first magnetic field at the location of the first magnetic field sensor; and a first magnetic field guiding arrangement for guiding the first magnetic field to the location of the first magnetic field sensor.

By directing (guiding) the magnetic fields to the measuring point, the magnetic signal in this area is bundled and amplified. The accuracy of the torque sensor can thus be improved. The torque sensor according to the invention can be further developed as follows.

One further development is that the torque sensor can further comprise a second magnetized region that generates a second magnetic field in response to a torque applied to the shaft, wherein the magnetization of the second magnetized region is opposite to the magnetization of the first magnetized region; a second magnetic field sensor for detecting the second magnetic field, wherein the second magnetic field sensor is adapted to output a signal in response to a strength of the second magnetic field at the location of the second magnetic field sensor; and a second magnetic field guiding arrangement for guiding the second magnetic field to the location of the second magnetic field sensor.

The provision of a second magnetized region, where the magnetization of the second magnetized region is opposite to the magnetization of the first magnetized region, enables good correction of the signal with respect to extraneous magnetic fields. In this way, the accuracy can be increased and, in particular, constant disturbance magnetic fields that are independent of the applied torque can be compensated for. The magnetic field is directed from the second area with the second magnetic field guide arrangement to the location of the second magnetic field sensor and amplified there.

However, one or more further magnetized areas can also be provided, such as a third magnetized area.

According to another further development, the first magnetic field guiding arrangement can comprise a first and a second magnetic field guiding element, with the first and second magnetic field guiding element being arranged on different sides, in particular opposite sides, of the first magnetic field sensor. This improves the bundling of the magnetic field from both sides of the first area at the location of the first magnetic field sensor.

Another further development is that the second magnetic field guiding arrangement can comprise a third and a fourth magnetic field guiding element, whereby the third and fourth magnetic field guiding elements are arranged on different sides, in particular opposite sides, of the second magnetic field sensor. The previously mentioned advantages apply here accordingly, i.e. the bundling of the magnetic field from both sides of the second area at the location of the second magnetic field sensor.

This can be further developed in such a way that the second and third magnetic field guiding elements are provided between the first and second magnetic field sensors and are formed in one piece.

According to another further development, each of the magnetic field guiding elements can comprise a metal sheet. In this way, the magnetic field can be precisely guided to the magnetic field sensor. The magnetic field within the metal sheet can essentially follow the direction of the sheet and emerge again at edges or bends in order to reach the magnetic field sensor.

This can be further developed in such a way that each metal sheet is flat or an end section of the respective metal sheet adjacent to the first magnetic field sensor is angled. This allows the magnetic field guided/conducted by the metal sheet to reach the magnetic field sensor.

Another further development is that the respective metal sheet is rectangular in a sheet plane or tapered towards the magnetic field sensor, in other words wedge-shaped in the direction of the magnetic field sensor. This further increases the bundling of the magnetic field at the location of the magnetic field sensor.

According to another further development, a material of the first or first and/or second magnetic field guiding arrangement can comprise a soft magnetic or a paramagnetic material. This is advantageous in that a possible permanent magnetization of the metal sheets and hysteresis effects can be avoided.

This can be further developed in that the material of the first or first and/or second magnetic field guiding arrangement can comprise a metal or a ceramic material with magnetizable metal particles or a plastic material with magnetizable metal particles.

Another further development is that the first and/or the second magnetic field sensor comprises one or more coils or is/are a sensor based on a magnetoresistive effect, in particular an AMR sensor, CMR sensor, GMR sensor, TMR sensor or a sensor based on the planar Hall effect. These magnetic field sensors have proven to be advantageous for measuring the magnetic fields, as their sensitivity in particular is comparatively high.

The first and/or the second magnetic field sensor can be arranged on a printed circuit board.

Further features and exemplary embodiments as well as advantages of the present invention are explained in more detail below with reference to the drawings. It is to be understood that the embodiments do not exhaust the scope of the present invention. It is further understood that some or all of the features described below may also be combined in other ways.

### BRIEF DESCRIPTION OF THE DRAWINGS

FIG. 1 shows an embodiment of the torque sensor according to the invention with metal sheets as a magnetic field guiding arrangement.

FIG. 2 shows various embodiments of the metal sheets according to FIG. 1.

FIG. 3 shows further embodiments of the metal sheets according to FIG. 1 or 2.

FIG. 4 shows an embodiment with vertically arranged sensors.

### DETAILED DESCRIPTION

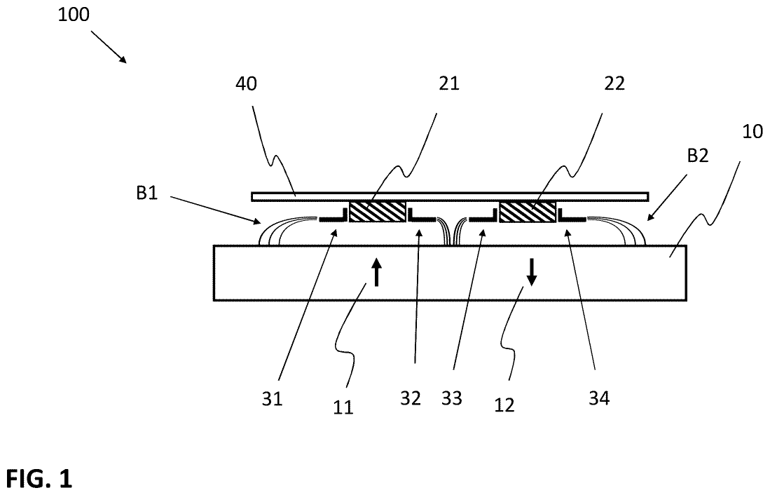

FIG. 1 shows an embodiment of the torque sensor 100 according to the invention.

The torque sensor 100 according to the invention comprises a shaft 10 having a first magnetized region 11, which generates a first magnetic field B1 in response to a torque applied to the shaft 10; a first magnetic field sensor 21 for detecting the first magnetic field B1, wherein the magnetic field sensor 21 is adapted to output a signal depending on a strength of the first magnetic field B1 at the location of the first magnetic field sensor 21; and a first magnetic field guiding arrangement 31, 32 for guiding the first magnetic field B1 to the location of the first magnetic field sensor 21.

The torque sensor 100 further comprises a second magnetized region 12 which generates a second magnetic field B2 depending on a torque applied to the shaft 10, wherein the magnetization of the second magnetized region 12 is opposite to the magnetization of the first magnetized region 11. The magnetizations are imprinted in opposite circumferential directions of the shaft 10 by pre-magnetization. A second magnetic field sensor 22 is provided for detecting the second magnetic field B2, wherein the second magnetic field sensor 22 is configured to output a signal as a function of a strength of the second magnetic field B2 at the location of the second magnetic field sensor 22. A second magnetic field guiding arrangement 33, 34 guides the second magnetic field B2 to the location of the second magnetic field sensor 22.

The first and second magnetic field sensors are arranged on a printed circuit board 40.

The first magnetic field guiding arrangement 31, 32 comprises a first magnetic field guiding element 31 and a second magnetic field guiding element 32. The second magnetic field guiding arrangement 33, 34 comprises a third magnetic field guiding element 33 and a fourth magnetic field guiding element 34.

The magnetic field guiding elements are each formed as metal sheets 31, 32, 33, 34 and may be arranged on respectively different sides, in particular opposite sides, of the first magnetic field sensor and may comprise a soft magnetic or paramagnetic material, or a ceramic material or plastic material with magnetizable metal particles.

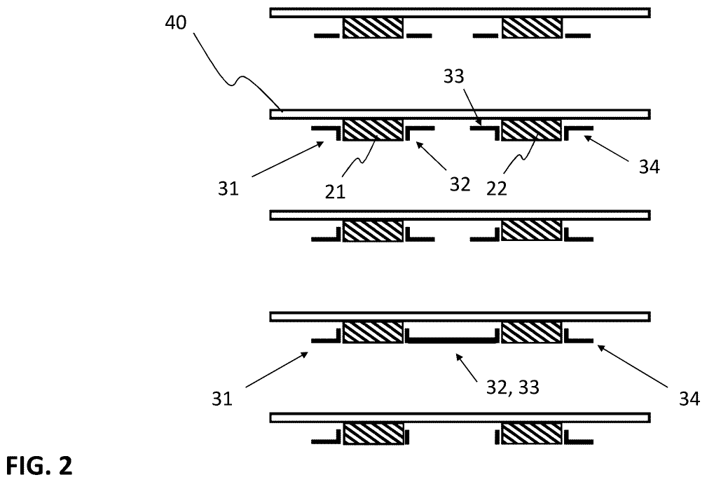

FIG. 2 shows various embodiments of the metal sheets according to FIG. 1.

The metal sheets can be formed flat, in one plane (first figure) or an end section may be angled downwards (second figure) or upwards (third figure), or tapered, adjacent or at the sensors 21, 22.

In the fourth figure, the second and third metal sheets 32, 33 are formed in one piece from above.

In the fifth figure, the second and third metal sheets 32, 33 are each formed only in a plane perpendicular to the printed circuit board.

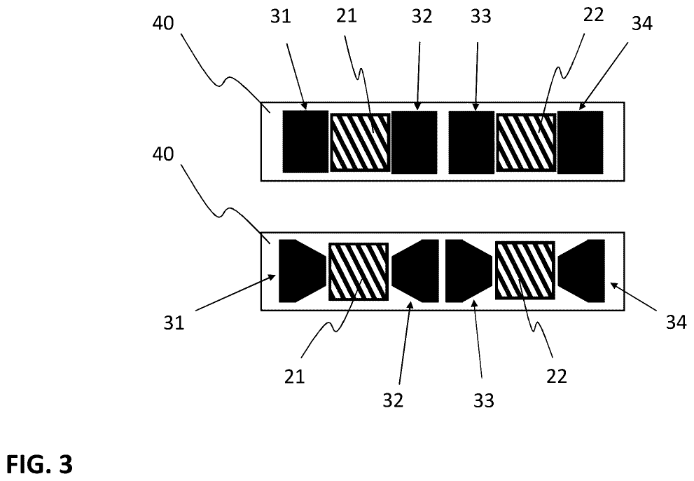

FIG. 3 shows further embodiments of the metal sheets according to FIG. 1 or 2.

In the upper figure, the metal sheets 31, 32, 33, 34 are rectangular in shape in the plane of the sheet, while in the lower figure they are wedge-shaped in the direction of the sensors 21, 22, which concentrates the magnetic field (or the magnetic field lines) more strongly on the sensors 21, 22.

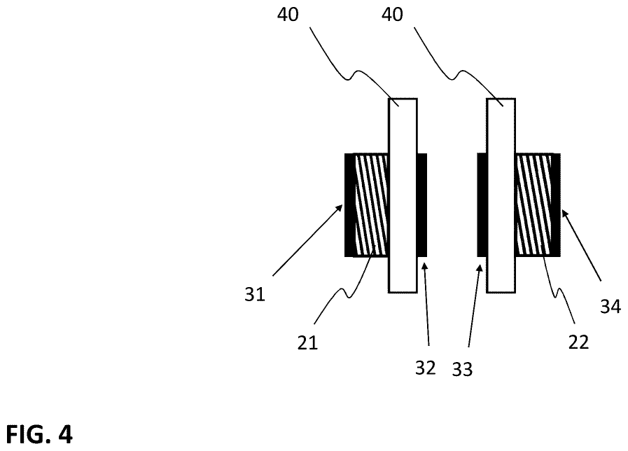

FIG. 4 shows an embodiment with vertically arranged sensors.

In this arrangement of the sensors 21, 22 on the PCBs 40, the magnetic field lines can also be guided through metal sheets 31, 32, 33, 34 in order to improve the signal. The first and/or the second magnetic field sensor may comprise one or more coils or is/are a sensor based on a magnetoresistive effect, in particular an AMR sensor, CMR sensor, GMR sensor, TMR sensor or a sensor based on the planar Hall effect.

The embodiments shown are merely exemplary and the full scope of the present invention is defined by the claims.

What is claimed is:

1. A torque sensor comprising:
a shaft having a first magnetized region which generates a first magnetic field in response to a torque applied to the shaft;
a first magnetic field sensor for detecting the first magnetic field, the magnetic field sensor being adapted to output a signal in response to a strength of the first magnetic field at a location of the first magnetic field sensor; and
a first magnetic field guiding arrangement for guiding the first magnetic field to the location of the first magnetic field sensor.

2. The torque sensor according to claim 1, further comprising:
a second magnetized region that generates a second magnetic field in response to a torque applied to the shaft, wherein the magnetization of the second magnetized region is opposite to the magnetization of the first magnetized region;
a second magnetic field sensor for detecting the second magnetic field, the second magnetic field sensor being adapted to output a signal depending on a strength of the second magnetic field at the location of the second magnetic field sensor; and
a second magnetic field guiding arrangement for guiding the second magnetic field to the location of the second magnetic field sensor.

3. The torque sensor according to claim 1, wherein the first magnetic field guiding arrangement comprises first and a second magnetic field guiding elements, wherein the first and second magnetic field guiding elements are arranged on respectively different sides, in particular opposite sides, of the first magnetic field sensor.

4. The torque sensor according to claim 2, wherein the second magnetic field guiding arrangement comprises a third and a fourth magnetic field guiding element, wherein the third and fourth magnetic field guiding element are arranged on respectively different sides, in particular opposite sides, of the second magnetic field sensor.

5. The torque sensor according to claim 4, wherein the second and third magnetic field guiding elements are provided between the first and second magnetic field sensors and are formed in one piece.

6. The torque sensor according to claim 3, wherein each of the first and second magnetic field guiding elements comprises a metal sheet.

7. The torque sensor according to claim 6, wherein each metal sheet is formed flat or an end section of a respective metal sheet adjacent to a first magnetic field sensor is formed at an angle.

8. The torque sensor according to claim 5, wherein a respective metal sheet is rectangular in a metal sheet plane or tapered towards the magnetic field sensor.

9. The torque sensor according to claim 2, wherein a material of one or both of the first magnetic field guiding arrangement and the second magnetic field guiding arrangement comprises a soft magnetic or a paramagnetic material.

10. The torque sensor according to claim 2, wherein a material of one or both of the first magnetic field guiding arrangement and the second magnetic field guiding arrangement comprises a metal or a ceramic material or a plastic material with magnetizable metal particles.

11. The torque sensor according to claim 2, wherein one or both of the first magnetic field sensor and the second magnetic field sensor comprises one or more coils or comprises one or more sensors based on a magnetoresistive effect, in particular an AMR sensor, CMR sensor, GMR sensor, TMR sensor or one or more sensors based on a planar Hall effect.

12. The torque sensor according to claim 2, wherein one or both of the first magnetic field sensor and the second magnetic field sensor are arranged on a printed circuit board.
